(19) United States
(12) Patent Application Publication
(10) Pub. No.: US 2025/0029637 A1
(43) Pub. Date: Jan. 23, 2025

(54) MULTI CONNECTOR GRIP AND STORAGE DEVICE TEST SYSTEM INCLUDING THE SAME

(71) Applicant: SAMSUNG ELECTRONICS CO., LTD., Suwon-si (KR)

(72) Inventors: Sanggeun YOO, Suwon-si (KR); Kwangkyu BANG, Suwon-si (KR)

(73) Assignee: SAMSUNG ELECTRONICS CO., LTD., Suwon-si (KR)

(21) Appl. No.: 18/738,658

(22) Filed: Jun. 10, 2024

(30) Foreign Application Priority Data
Jul. 18, 2023 (KR) 10-2023-0093339

(51) Int. Cl. G11B 33/12; H01R 13/58

(52) U.S. Cl. CPC G11B 33/126; G11B 33/127; H01R 13/58; H01R 2201/20

(57) ABSTRACT

A multi connector grip includes a first surface including a first cable connector groove configured to accommodate a first cable connector, the first cable connector groove having a first cable connector groove depth and the first cable connector having a first depth; and a second surface opposite to the first surface and including a second cable connector groove configured to accommodate a second cable connector, the second cable connector groove having a second cable connector groove depth and the second cable connector having a second depth, wherein a difference between the first cable connector groove depth and the second cable connector groove depth is equal to a difference between the first depth and the second depth.

### CROSS-REFERENCE TO RELATED APPLICATION

This application is based on and claims priority under 35 U.S.C. § 119 to Korean Patent Application Nos. 10-2023-0093339, filed on Jul. 18, 2023, in the Korean Intellectual Property Office, the disclosure of which is incorporated by reference herein in its entirety.

### BACKGROUND

The present disclosure relates to a multi connector grip and a storage device test system including the same, and more particularly, to a multi connector grip compatible with a plurality of cable connectors and a storage device test system including the same.

When testing storage devices, storage connectors of the storage devices and cable connectors connected to a test device need to be connected to each other.

When connection and disconnection between various storage devices and cable connectors are repeatedly performed, there is a risk of poor contact between the cable connectors and the storage connectors.

### SUMMARY

Example embodiments provide a multi connector grip compatible with a plurality of cable connectors and a storage device test system including the same.

According to an aspect of an example embodiment, a multi connector grip includes: a first surface including a first cable connector groove configured to accommodate a first cable connector, the first cable connector groove having a first cable connector groove depth and the first cable connector having a first depth; and a second surface opposite to the first surface and including a second cable connector groove configured to accommodate a second cable connector, the second cable connector groove having a second cable connector groove depth and the second cable connector having a second depth, wherein a difference between the first cable connector groove depth and the second cable connector groove depth is equal to a difference between the first depth and the second depth.

According to an aspect of an example embodiment, a storage device test system includes: a storage rack including a first slot and a second slot; a first storage device inserted into the first slot and including a first storage connector; a second storage device inserted into the second slot and including a second storage connector; a test device configured to test the first storage device and the second storage device; a first cable connector connected to a first cable extending from the test device; a second cable connector connected to a second cable extending from the test device; a first multi connector grip coupled to the first slot and configured to fix a position of the first cable connector; and a second multi connector grip coupled to the second slot and configured to fix a position of the second cable connector, wherein the first cable connector and the first storage connector are connected to each other at a first coupling surface of the first multi connector grip, the second cable connector and the second storage connector are connected to each other at a second coupling surface of the second multi connector grip, the first coupling surface of the first multi connector grip and the second coupling surface of the second multi connector grip have different structures, a third coupling surface of the first multi connector grip and the second coupling surface of the second multi connector grip have a same structure, and a fourth coupling surface of the second multi connector grip and the first coupling surface of the first multi connector grip have a same structure.

According to an aspect of an example embodiment, an automated storage device test system includes: a storage rack including a first slot and a second slot; a robot arm configured to, based on coordinates of the first slot and the second slot, insert a first storage device into the first slot and a second storage device into the second slot; a test device configured to test the first storage device and the second storage device; a first cable connector connected to a first cable extending from the test device; a second cable connector connected to a second cable extending from the test device; a first multi connector grip coupled to the first slot and configured to fix a position of the first cable connector; and a second multi connector grip coupled to the second slot and configured to fix a position of the second cable connector, wherein the first cable connector and a first storage connector of the first storage device are connected to each other at a first coupling surface of the first multi connector grip, the second cable connector and a second storage connector of the second storage device are connected to each other at a second coupling surface of the second multi connector grip, and the first coupling surface of the first multi connector grip and the second coupling surface of the second multi connector grip have different structures.

### BRIEF DESCRIPTION OF THE DRAWINGS

The above and/or other aspect will be more clearly understood from the following detailed description of embodiments taken in conjunction with the accompanying drawings, in which:

FIG. 1 is a view illustrating an automated storage device test system according to one or more embodiments;

FIGS. 2A, 2B, and 2C are views illustrating an automated storage device test system according to one or more embodiments;

FIG. 3 is a view illustrating insertion of storage devices according to one or more embodiments;

FIGS. 4A and 4B are views illustrating cable connectors according to one or more embodiments;

FIGS. 5A and 5B are views illustrating a multi connector grip according to one or more embodiments;

FIGS. 6A and 6B are views illustrating a multi connector grip that grips a first cable connector according to one or more embodiments;

FIGS. 7A and 7B are views illustrating a multi connector grip that grips a second cable connector according to one or more embodiments;

FIG. 8 is a view illustrating a multi connector grip according to one or more embodiments;

FIGS. 9A and 9B are views illustrating the multi connector grip according to one or more embodiments;

FIGS. 10A and 10B are views illustrating the multi connector grip according to one or more embodiments;

FIG. 11 is a view illustrating a multi connector grip according to one or more embodiments;

FIGS. 12A, 12B, 12C, and 12D are views respectively illustrating first, second, third, and fourth coupling surfaces of the multi connector grip according to one or more embodiments;

FIG. 13 is a view illustrating operation of the multi connector grip according to one or more embodiments; and

FIGS. 14A and 14B are views illustrating a rotatable multi connector grip according to one or more embodiments.

### DETAILED DESCRIPTION

Hereinafter, various embodiments are described with reference to the accompanying drawings.

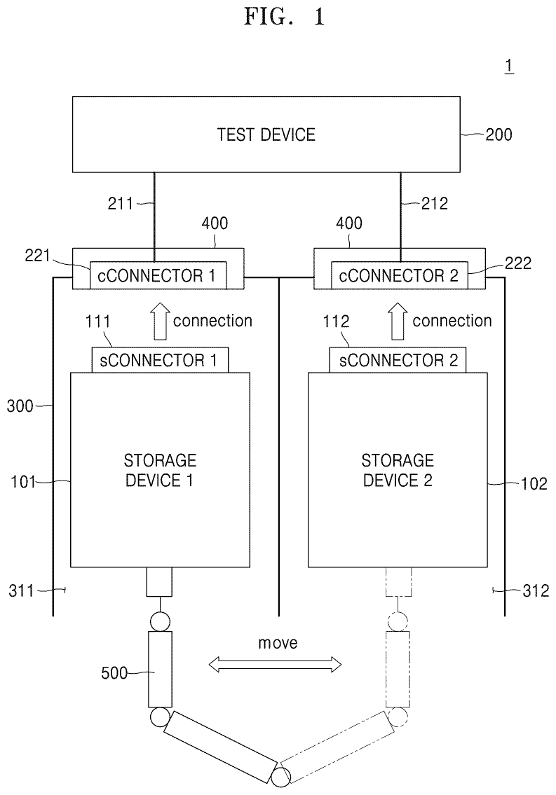

FIG. 1 is a view illustrating an automated storage device test system 1 according to one or more embodiments.

Referring to FIG. 1, the automated storage device test system 1 may include a first storage device 101, a second storage device 102, a test device 200, a storage rack 300, and a robot arm 500.

The first and second storage devices 101 and 102 may include nonvolatile memory devices. In one or more embodiments, the first and second storage devices 101 and 102 may be provided as memory devices which are built in or detachable from an electronic device. For example, the first and second storage devices 101 and 102 may be provided in various forms, such as an embedded universal flash storage (UFS) memory device, an embedded multi-media card (eMMC), a solid state drive (SSD), a UFS memory card, a compact flash (CF) memory card, a secure digital (SD) memory card, a micro secure digital (micro-SD) memory card, a mini secure digital (mini-SD) memory card, an extreme digital (xD) memory card, and a memory stick.

The test device 200 may perform a plurality of test operations to test the first and second storage devices 101 and 102. For example, the test device 200 may performs a write operation and a read operation on the first and second storage devices 101 and 102 and test the characteristics of the first and second storage devices 101 and 102 based on the write and read operations.

A first cable connector (cCONNECTOR 1) 221 and a second cable connector (cCONNECTOR 2) 222 may be coupled and fixed to the storage rack 300. Specifically, multi connector grips 400 may be coupled and fixed to the storage rack 300 while respectively gripping the first and second cable connectors 221 and 222. The first cable connector 221 may be connected to the test device 200 via a first cable 211, and the second cable connector 222 may be connected to the test device 200 via a second cable 212.

The first and second storage devices 101 and 102 may be inserted into first and second slots 311 and 312, respectively, which are provided in the storage rack 300. Specifically, the robot arm 500 may move based on the coordinates of the first and second slots 311 and 312 and insert the first and second storage devices 101 and 102 into first and second slots 311 and 312, respectively, at positions to which the robot arm 500 moves.

When the robot arm 500 inserts the first storage device 101 into the first slot 311, a first storage connector (sCONNECTOR 1) 111 of the first storage device 101 may be connected to the first cable connector 221. When the robot arm 500 inserts the second storage device 102 into the second slot 312, a second storage connector (sCONNECTOR 2) 112 of the second storage device 102 may be connected to the second cable connector 222.

Each of the first and second storage devices 101 and 102 may communicate with the test device 200 via one of various interfaces. Each of the first and second storage devices 101 and 102 may communicate with the test device 200 via various interfaces, such as a universal serial bus (USB), a multimedia card (MMC), an embedded MMC (eMMC), a peripheral component interconnection (PCI), a PCI-express (PCI-E), an advanced technology attachment (ATA), a serial-ATA, a parallel-ATA, a small computer small interface (SCSI), an enhanced small disk interface (ESDI), integrated drive electronics (IDE), a firewire, a UFS, and a nonvolatile memory express (NVMe).

In one or more embodiments, the first cable connector 221 and the second cable connector 222 may be configured according to the same connector standard. For example, the first cable connector 221 and the second cable connector 222 may be configured according to one connector standard among M.2, U.2, enterprise and data center standard form factor (EDSFF), and mini-serial advanced technology attachment (mSATA). For example, the first cable connector 221 and the second cable connector 222 may have the same pin map. Specifically, the numbers and types of pins in the first cable connector 221 and the second cable connector 222 may be same. The pin maps of the first cable connector 221 and the second cable connector 222 may be set based on the same standard specification.

Even though the first cable connector 221 and the second cable connector 222 are configured according to the same connector standard, the characteristics of signals transmitted/received via the first cable connector 221 and the second cable connector 222 may be different from each other depending on the structures of the first cable connector 221 and the second cable connector 222. In one or more embodiments, the characteristics (e.g., a voltage level, a delay time, a signal integrity, an eye diagram, etc.) of signals transmitted/received via a first pin of the first cable connector 221 may be different from the characteristics of signals transmitted/received via a first pin of the second cable connector 222. The structures of the first cable connector 221 and the second cable connector 222 may be different from each other depending on manufacturers. When evaluating storage devices, different cable connectors may be used depending on the signals to be evaluated. Accordingly, repeated coupling and decoupling between the cable connector and the storage connector may be performed to evaluate various signals.

However, when coupling and decoupling between the first and second cable connectors 221 and 222 and the first and second storage connectors 111 and 112 are repeated, the positions of the first and second cable connectors 221 and 222 may change. When the robot arm 500 attempts to respectively connect the first and second cable connectors 221 and 222 and the first and second storage connectors 111 and 112 to each other in a state in which the positions of the first and second cable connectors 221 and 222 have changed, contact failure or connector damage may occur.

The multi connector grips 400 according to one or more embodiments are fixed to the storage rack 300 and respectively grip the first and second cable connectors 221 and 222, and thus, the coupling positions of the first and second cable connectors 221 and 222 may be fixed. Also, each of coupling surfaces of the multi connector grips 400 may have a structure optimized to grip the corresponding cable connector. For example, a first coupling surface of the multi connector grip 400 may have a structure that matches the first cable connector 221, and a second coupling surface of the multi connector grip 400 may have a structure that matches the second cable connector 222.

Therefore, the multi connector grip 400 may establish connections between the first and second storage connectors 111 and 112 and the first and second cable connectors 221 and 222 using the robot arm 500 without poor contact or damage to connectors.

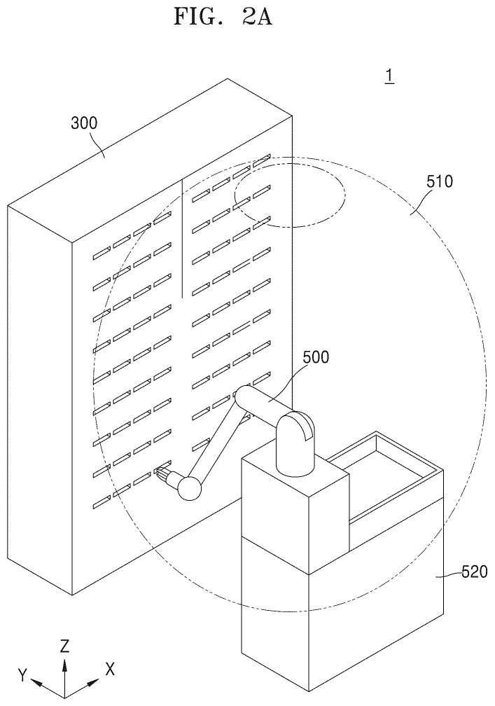

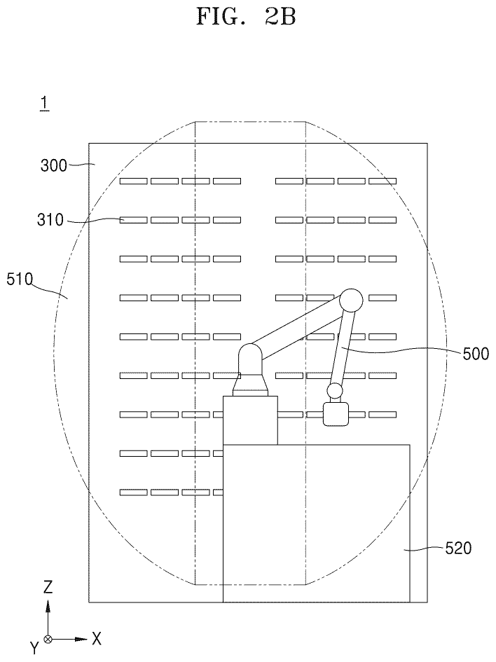

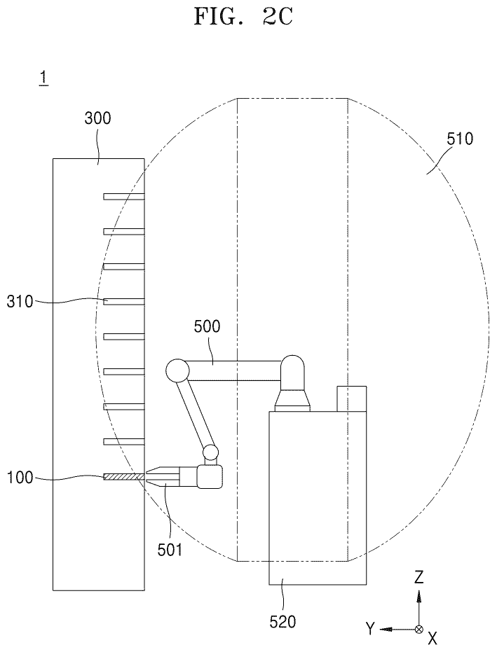

FIGS. 2A to 2C are views illustrating the automated storage device test system 1 according to one or more embodiments. FIGS. 2A to 2C may be described below with reference to FIG. 1.

Referring to FIG. 2A, the automated storage device test system 1 may include a storage tray 520 and the robot arm 500.

The storage tray 520 may be provided as a movable or fixed type. The storage tray 520 may accommodate various storage devices (e.g., 101 and 102 in FIG. 1). The robot arm 500 may move freely within a movable range 510 having a spherical shape. The robot arm 500 may insert storage devices, which are stored in the storage tray 520, into slots (e.g., 311 and 312 in FIG. 1) of the storage rack 300. The robot arm 500 may include a plurality of joints, and each of the joints may include a motor that provides rotational movement.

When the robot arm 500 inserts the storage device into the slot, the storage connector of the storage device and the cable connector may be connected to each other. Since the cable connector is fixed to the slot in advance by the multi connector grip (400 in FIG. 1), the position of the cable connector may be maintained constant (remain fixed). Accordingly, even if the insertion of the storage device is repeated based on the coordinates of the slot, a smooth connection between the storage connector and the cable connector is possible.

Referring to FIG. 2B, the storage rack 300 may include at least one slot 310. The slots 310 may include spaces into which the storage devices (e.g., 101 and 102 in FIG. 1) are inserted. The robot arm 500 may approach the slot 310 based on the coordinates of the slot 310 and insert the storage device into the slot 310.

Referring to FIG. 2C, an end-of-arm 501 of the robot arm 500 may push a storage device 100 into the slot 310. When the end-of-arm 501 places the storage device 100 into the slot 310, the storage connector of the storage device 100 and the cable connector may be connected to each other. The cable connector may be fixed to the slot 310 in advance. Specifically, the multi connector grip (400 in FIG. 1) may be coupled to the storage rack 300 while gripping the cable connector. The position of the cable connector is maintained even when repeated test operations are performed, and thus, the connection between the storage connector and the cable connector may be established without poor contact between the cable connector and the storage connector or damage to the cable connector and the storage connector.

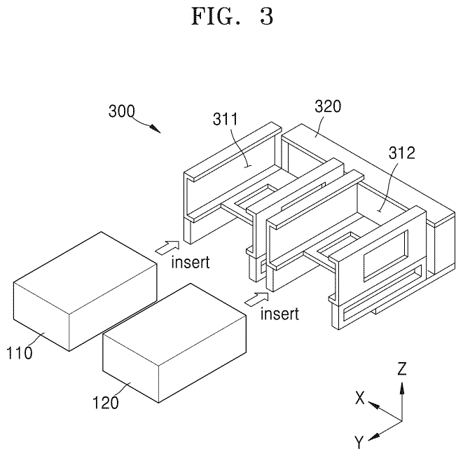

FIG. 3 is a view illustrating insertion of first and second storage devices 101 and 102 according to one or more embodiments. FIG. 3 may be described below with reference to FIGS. 1 and 2.

Referring to FIG. 3, the first and second storage devices 101 and 102 may be inserted into first and second slots 311 and 312, respectively, by a robot arm 500. Although the first and second storage devices 102 and 102 are illustrated as being inserted in a Y-axis direction, embodiments are not limited thereto. The first and second storage devices 101 and 102 may be inserted into the first and second slots 311 and 312 in various directions.

The multi connector grip 400 of FIG. 1 may be coupled to the storage rack 300, corresponding to each of the first and second slots 311 and 312. Specifically, the storage rack 300 may include a board 320, and the multi connector grip 400 may be coupled to the board 320. Corresponding to the first slot 311, the multi connector grip 400 may be coupled to the board 320 while a first coupling surface of the multi connector grip 400 grips a first cable connector 221. Corresponding to the second slot 312, the multi connector grip 400 may be coupled to the board 320 while a second coupling surface of the multi connector grip 400 grips a second cable connector 222.

As the first and second storage devices 101 and 102 are inserted into the first and second slots 311 and 312, respectively, the first and second storage connectors 111 and 112 may be connected to the first and second cable connectors 221 and 222, respectively, which are gripped by the multi connector grip 400.

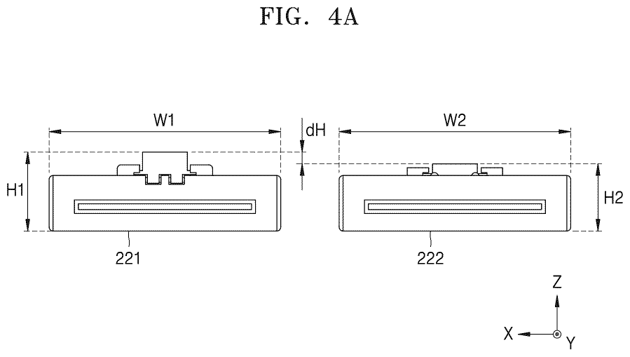

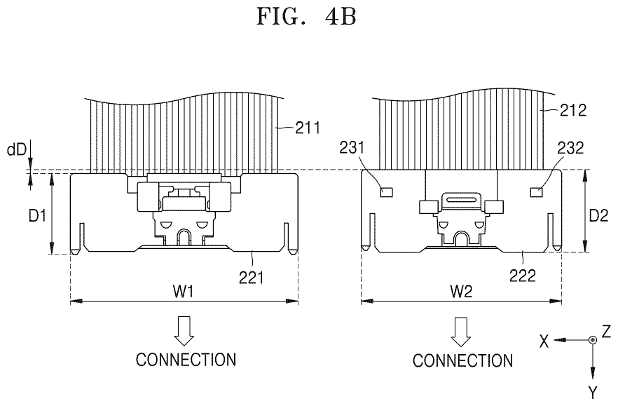

FIGS. 4A and 4B are views illustrating first and second cable connectors 221 and 222 according to one or more embodiments. Specifically, FIG. 4A is a plan view of the first and second cable connectors 221 and 222 in the Y-axis direction, and FIG. 4B is a plan view of the first and second cable connectors 221 and 222 in the Z-axis direction.

As used herein, the length of a cable connector in the Z-axis direction may be referred to as a height, the length of the cable connector in the X-axis direction may be referred to as a width, and the length of the cable connector in the Y-axis direction may be referred to as a depth.

Referring to FIG. 4A, the first cable connector 221 and the second cable connector 222 may have the same pin map. That is, the numbers and types of pins in the first cable connector 221 and the second cable connector 222 may be same. The pin maps of the first cable connector 221 and the second cable connector 222 may be formed based on the same standard specification.

The first cable connector 221 may have a first height H1 and a first width W1. The second cable connector 222 may have a second height H2 and a second width W2. The housing size of a cable connector may vary depending on the manufacturers of the cable connector. That is, the first height H1 and the second height H2 may be different from each other, and the first width W1 and the second width W2 may be different from each other. The first height H1 may be greater than the second height H2 by a height difference dH.

Referring to FIG. 4B, the first cable connector 221 may have a first depth D1, and the second cable connector 222 may have a second depth D2. The first depth D1 and the second depth D2 may be different from each other. The first depth D1 may be less than the second depth D2 by a depth difference dD. Dip structures 231 and 232 may be formed on the upper surface of the second cable connector 222. The dip structures 231 and 232 may include concave portions on the upper surface of the second cable connector 222.

According to one or more embodiments, a multi connector grip 400 may include coupling surfaces having different structures depending on the dimensions of the first and second cable connectors 221 and 222. That is, a first surface of the multi connector grip 400 may match the structure of the first cable connector 221, and a second surface of the multi connector grip 400 may match the structure of the second cable connector 222. Accordingly, the multi connector grip 400 may provide compatibility for gripping a plurality of cable connectors.

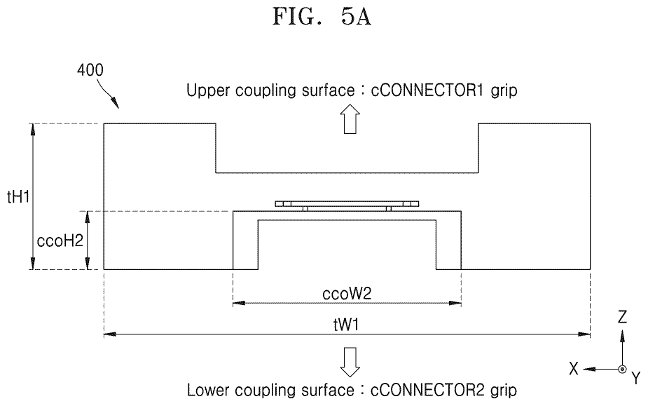

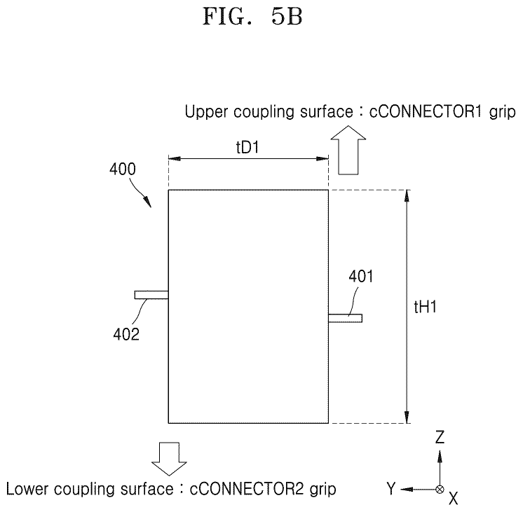

FIGS. 5A and 5B are views illustrating a multi connector grip 400 according to one or more embodiments. Specifically, FIG. 5A is a plan view of the multi connector grip 400 in the Y-axis direction, and FIG. 5B is a plan view of the multi connector grip 400 in the X-axis direction.

Referring to FIG. 5A, the multi connector grip 400 may have two coupling surfaces. The upper coupling surface may be used when gripping a first cable connector 221, and the lower coupling surface may be used when gripping a second cable connector 222. Referring to FIG. 5A, when viewed in the Y-axis direction, the outline of the multi connector grip 400 may have an H shape with a first total height tH1 and a first total width tW1.

Referring to FIG. 5B, when viewed in the X-axis direction, the outline of the multi connector grip 400 may have a rectangular shape with the first total height tH1 and a first total depth tD1. A first support member 401 and a second support member 402 may protrude in the (+)Y-axis or (−)Y-axis direction. The first cable 211 may be seated on the first support member 401, and the second cable 212 may be seated on the second support member 402.

The multi connector grip 400 grips the first cable connector 221 and the second cable connector 222 using the upper and lower coupling surfaces that are opposite to each other in the Z-axis direction, and thus, the first total height tH1 of the multi connector grip 400 may be greater than the sum of the first height H1 and the second height H2. In the multi connector grip 400, a space for gripping the first cable connector 221 and a space for gripping the second cable connector 222 may at least partially overlap each other in the Z-axis direction. Accordingly, the first total depth tD1 of the multi connector grip 400 may be less than the sum of the first depth D1 and the second depth D2.

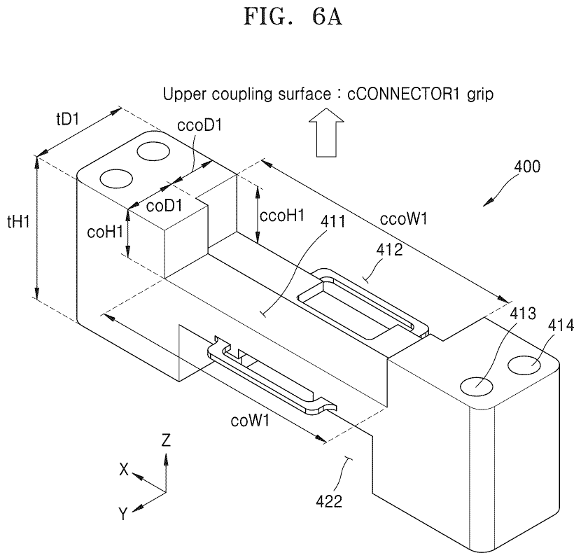

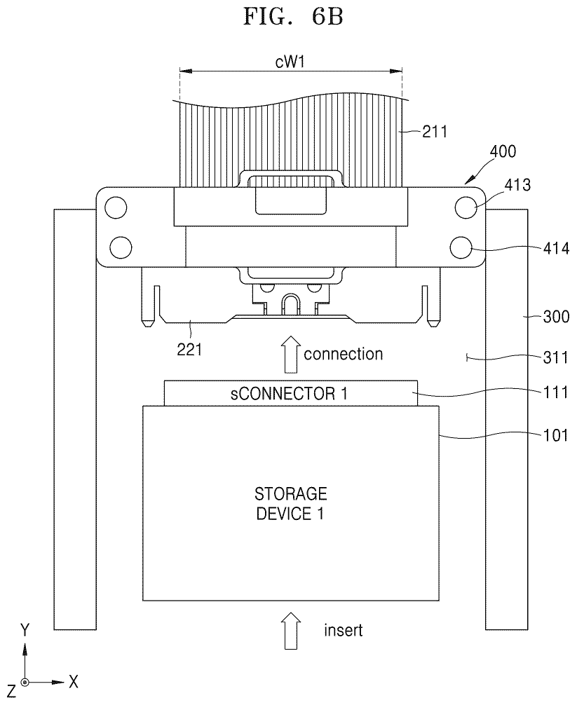

FIGS. 6A and 6B are views illustrating a multi connector grip 400 that grips a first cable connector 221 according to one or more embodiments.

Referring to FIG. 6A, the upper coupling surface of the multi connector grip 400 may have a structure that grips the first cable connector 221.

Specifically, a first cable 211 may be seated in a first cable groove 411 on the upper coupling surface, and the first cable connector 221 may be gripped in a first cable connector groove 412 on the upper coupling surface.

The first cable groove 411 may be formed in a size to accommodate the first cable 211. Specifically, the first cable groove 411 may have a first cable groove width coW1, a first cable groove depth coD1, and a first cable groove height coH1. The first cable groove depth coD1 may have a value obtained by subtracting a first cable connector groove depth ccoD1 from a total depth tD. The first cable groove width coW1 may be greater than the width of the first cable 211. The first cable groove height coH1 may be greater than the thickness of the first cable 211.

The first cable connector groove 412 may grip the exterior of the first cable connector 221. Specifically, the first cable connector groove 412 may have a first cable connector groove width ccoW1, the first cable connector groove depth ccoD1, and a first cable connector groove height ccoH1. Referring to FIGS. 4A and 4B, the first cable connector groove width ccoW1 may be equal to the first width W1. The first cable connector groove height ccoH1 may be equal to the first height H1. The first cable connector groove depth ccoD1 may be less than the first depth D1. However, embodiments are not limited thereto, and the first cable connector groove depth ccoD1 may be equal to or greater than the first depth D1. Also, the first cable connector groove width ccoW1, the first cable connector groove depth ccoD1, and the first cable connector groove height ccoH1 may be set such that the first cable connector groove 412 grips the exterior of the first cable connector 221.

The first cable connector groove width ccoW1 may be greater than the first cable groove width coW1. The first cable connector 221 is gripped in the first cable connector groove 412, and the first cable 211 is seated in the first cable groove 411. Accordingly, the first cable connector 221 may be prevented from being separated in the Y-axis direction.

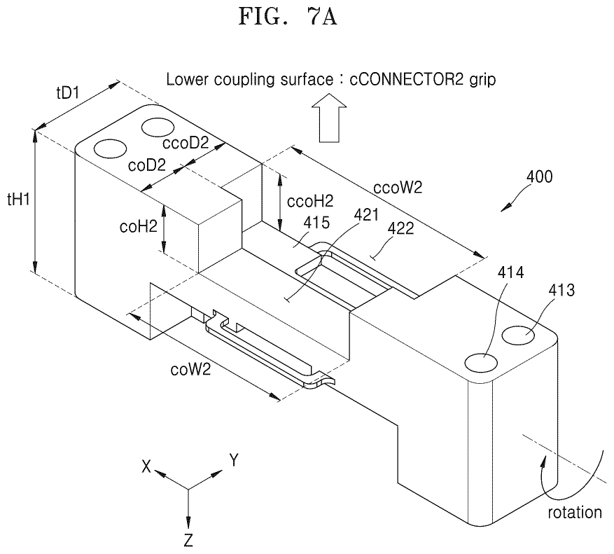

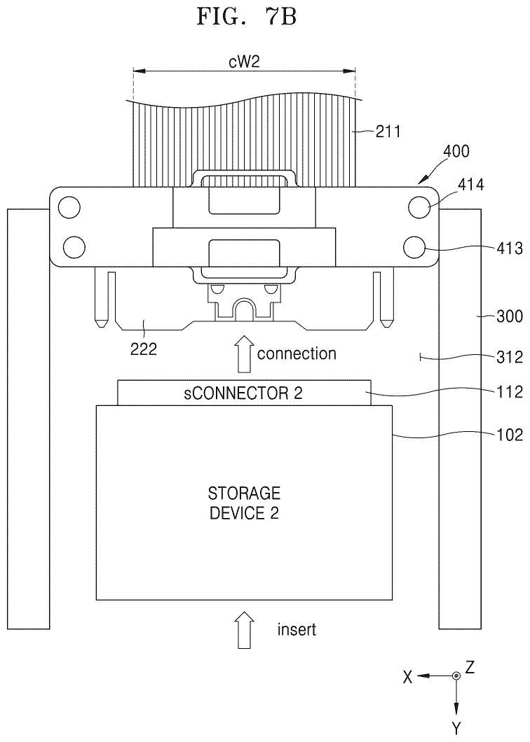

Referring to FIGS. 4A, 4B, 6A, and 7A, the first cable connector groove depth ccoD1 may be less than a second cable connector groove depth ccoD2 of FIG. 7A by a depth difference dD. Also, the first cable connector groove height ccoH1 may be less than a second cable connector groove height ccoH2 of FIG. 7A by a height difference dH. In addition, the first cable connector groove width ccoW1 may be less than a second cable connector groove width ccoW2 of FIG. 7A by a width difference dW. Accordingly, the upper coupling surface of the multi connector grip 400 may have a structure that matches the first cable connector 221. The lower coupling surface of the multi connector grip 400, which overlaps the upper coupling surface in the vertical direction (i.e., the Z-axis direction), may include a second cable connector groove 422 and a second cable groove 421.

Referring to FIG. 6B, the multi connector grip 400 may be coupled to the storage rack 300 such that the upper coupling surface of the multi connector grip 400 is oriented in the (−)Z-axis direction. The first cable connector 221 is located below the multi connector grip 400 (i.e., in the (−)Z-axis direction), and thus, the first cable connector 221 may be prevented from being separated in the (+)Z-axis direction. Specifically, the multi connector grip 400 may be coupled to a portion of the storage rack 300 (e.g., the board 320 in FIG. 3) by a connection member (e.g., a screw) inserted into a connector fixing hole 414. The multi connector grip 400 may include a cable fixing hole 413, and the first cable connector 221 may be fixed inside the multi connector grip 400 by a connection member inserted into the cable fixing hole 413. In a state in which the first cable connector 221 is positioned on a portion of the storage rack 300 (e.g., the board 320 in FIG. 3), the multi connector grip 400 may be coupled onto the first cable connector 221. Accordingly, the first cable connector 221 may be prevented from being separated in the (−)Z-axis direction by the portion of the storage rack 300.

The first cable 211 may be accommodated in the first cable groove 411 of the multi connector grip 400. A width cW1 of the first cable 211 may be less than the first cable groove width coW1. The first cable connector 221 may be gripped in the first cable connector groove 412 of the multi connector grip 400.

In a state in which the first cable connector 221 is gripped, a robot arm 500 may insert a first storage device 101 into a first slot 311. A first storage connector 111 of the first storage device 101 may be connected to the first cable connector 221.

FIGS. 7A and 7B are views illustrating the multi connector grip 400 that grips a second cable connector 222 according to one or more embodiments.

FIG. 7A is a view obtained by rotating the multi connector grip 400 of FIG. 6A by 180 degrees in the X-axis direction. Referring to FIG. 7A, the lower coupling surface of the multi connector grip 400 may have a structure that grips the second cable connector 222.

Specifically, a second cable 212 may be seated in a second cable groove 421 in the lower coupling surface of the multi connector grip 400, and the second cable connector 222 may be gripped in a second cable connector groove 422 in the lower coupling surface.

The second cable groove 421 may be formed in a size to accommodate the second cable 212. Specifically, the second cable groove 421 may have a second cable groove width coW2, a second cable groove depth coD2, and a second cable groove height coH2. The second cable groove depth coD2 may have a value obtained by subtracting a second cable connector groove depth ccoD2 from the total depth tD. The second cable groove width coW2 may be greater than the width of the second cable 212. The second cable groove height coH2 may be greater than the thickness of the second cable 212.

In one or more embodiments, protruding structures may be formed on the lower coupling surface of the multi connector grip 400 at positions corresponding to the dip structures (231 and 232 in FIG. 4B) of the second cable connector 222. Specifically, when the second cable connector 222 is gripped in the second cable connector groove 422, the upper surface of the second cable connector 222 may be in contact with a support surface 415. Therefore, the protruding structures may be formed at positions on the support surface 415 that are in contact with the dip structures (231 and 232 in FIG. 4B) of the second cable connector 222. The protruding structures may be fitted with the dip structures 231 and 232 to strengthen a fixing force between the multi connector grip 400 and the second cable connector 222.

The second cable connector groove 422 may grip the exterior of the second cable connector 222. Specifically, the second cable connector groove 422 may have the second cable connector groove width ccoW2, the second cable connector groove depth ccoD2, and the second cable connector groove height ccoH2. Referring to FIGS. 4A and 4B, the second cable connector groove width ccoW2 may be equal to the second width W2. The second cable connector groove height ccoH2 may be equal to the second height H2. The second cable connector groove depth ccoD2 may be less than the second depth D2. However, embodiments are not limited thereto, and the second cable connector groove depth ccoD2 may be equal to or greater than the second depth D2. Also, the second cable connector groove width ccoW2, the second cable connector groove depth ccoD2, and the second cable connector groove height ccoH2 may be set such that the second cable connector groove 422 grips the exterior of the second cable connector 222.

The second cable connector groove width ccoW2 may be greater than the second cable groove width coW2. The second cable connector 222 is gripped in the second cable connector groove 422, and the second cable 212 is seated in the second cable groove 421. Accordingly, the second cable connector 222 may be prevented from being separated in the Y-axis direction.

Referring to FIGS. 4A, 4B, 6A, and 7A, the second cable connector groove depth ccoD2 may be greater than the first cable connector groove depth ccoD1 of FIG. 6A by the depth difference dD. Also, the second cable connector groove height ccoH2 may be greater than the first cable connector groove height ccoH1 of FIG. 6A by the height difference dH. In addition, the second cable connector groove width ccoW2 may be greater than the first cable connector groove width ccoW1 of FIG. 6A by the width difference dW. Accordingly, the lower coupling surface of the multi connector grip 400 may have a structure that matches the second cable connector 222. The upper coupling surface of the multi connector grip 400, which overlaps the lower coupling surface in the vertical direction (i.e., the Z-axis direction), may include the first cable connector groove 412 and the first cable groove 411.

Referring to FIG. 7B, the multi connector grip 400 may be coupled to the storage rack 300 such that the lower coupling surface of the multi connector grip 400 is oriented in the (−)Z-axis direction. The second cable connector 222 is located below the multi connector grip 400 (i.e., in the (−)Z-axis direction), and thus, the second cable connector 222 may be prevented from being separated in the (+)Z-axis direction. Specifically, the multi connector grip 400 may be coupled to a portion of the storage rack 300 (e.g., the board 320 in FIG. 3) by a screw inserted into a connector fixing hole 414. The multi connector grip 400 may include a cable fixing hole 413, and the second cable connector 222 may be fixed inside the multi connector grip 400 by a connection member inserted into the cable fixing hole 413. In a state in which the second cable connector 222 is positioned on a portion of the storage rack 300 (e.g., the board 320 in FIG. 3), the multi connector grip 400 may be coupled onto the second cable connector 222. Accordingly, the second cable connector 222 may be prevented from being separated in the (−)Z-axis direction by the portion of the storage rack 300.

The second cable 212 may be accommodated in the second cable groove 421 of the multi connector grip 400. A width cW2 of the second cable 212 may be less than the second cable groove width coW2 of the second cable groove 421. The second cable connector 222 may be gripped in the second cable connector groove 422 of the multi connector grip 400.

In a state in which the second cable connector 222 is gripped in the second cable connector groove 422, the robot arm 500 may insert a second storage device 102 into a second slot 312. The second storage connector 112 of the second storage device 102 may be connected to the second cable connector 222.

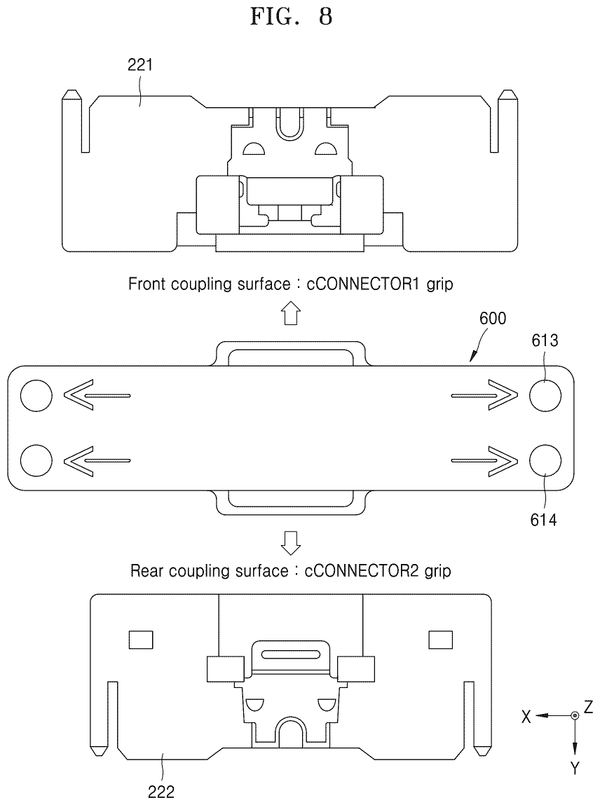

FIG. 8 is a view illustrating a multi connector grip 600 according to one or more embodiments.

In the multi connector grip 400 described above with reference to FIGS. 5A to 7B, the upper and lower coupling surfaces opposite to each other in the Z-axis direction grip the first cable connector 221 and the second cable connector 222, respectively. On the other hand, in a multi connector grip 600 of FIG. 8, the front and rear coupling surfaces opposite to each other in the Y-axis direction may grip a first cable connector 221 and a second cable connector 222, respectively. The multi connector grip 600 may include a first fixing hole 613 and a second fixing hole 614. The multi connector grip 600 may be coupled to a portion of the storage rack 300 (e.g., the board 320 in FIG. 3) by connection members (e.g., screws) inserted into the first and second fixing holes 613 and 614.

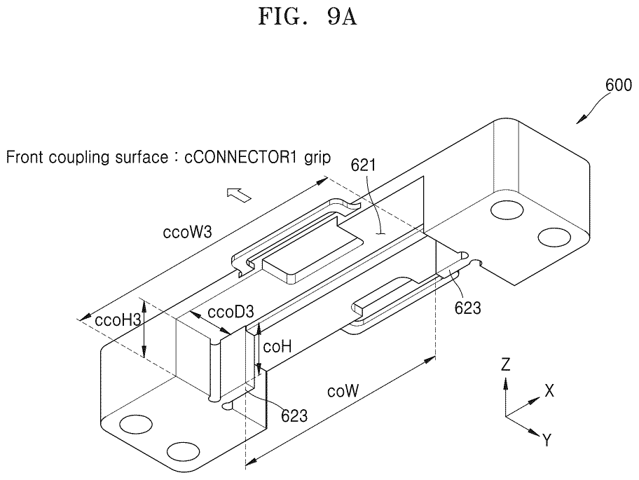

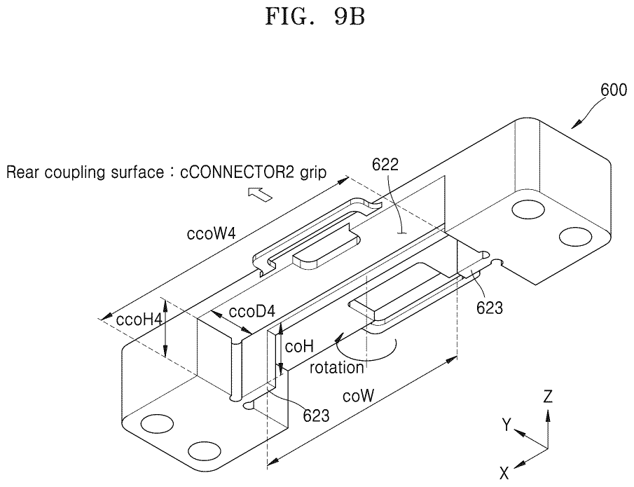

FIGS. 9A and 9B are views illustrating the multi connector grip 600 according to one or more embodiments.

Referring to FIG. 9A, the front coupling surface of the multi connector grip 600 may have a structure that grips the first cable connector 221.

Specifically, a third cable connector groove 621 of the front coupling surface of the multi connector grip 600 may grip the exterior of the first cable connector 221. Specifically, the third cable connector groove 621 may have a third cable connector groove width ccoW3, a third cable connector groove depth ccoD3, and a third cable connector groove height ccoH3. Referring to FIGS. 4A, 4B, and 9A, the third cable connector groove width ccoW3 may be equal to the first width W1. The third cable connector groove height ccoH3 may be equal to the first height H1. The third cable connector groove depth ccoD3 may be less than the first depth D1. However, embodiments are not limited thereto, and the third cable connector groove depth ccoD3 may be equal to or greater than the first depth D1. Also, the third cable connector groove width ccoW3, the third cable connector groove depth ccoD3, and the third cable connector groove height ccoH3 may be set such that the third cable connector groove 621 grips the exterior of the first cable connector 221.

The multi connector grip 600 may include a movement restriction wall 623 that makes a division between the front coupling surface and the rear coupling surface. When the first cable connector 221 is gripped in the third cable connector groove 621, the movement restriction wall 623 may prevent the first cable connector 221 from moving in the Y-axis direction.

A space between adjacent movement restriction walls 623 may be referred to as a cable groove, and the cable groove may have a cable groove height coH and a cable groove width coW. When the first cable connector 221 is gripped on the front coupling surface, a portion of a first cable 211 may be seated on the cable groove and the first cable 211 may extend in the Y-axis direction. Therefore, the cable groove width coW may be greater than the width of the first cable 211. The cable groove height coH may be greater than the thickness of the first cable 211.

FIG. 9B is a view obtained by rotating the multi connector grip 600 of FIG. 9A by 180 degrees in the Z-axis direction. Referring to FIG. 9B, the rear coupling surface of the multi connector grip 600 may have a structure that grips the second cable connector 222.

Specifically, a fourth cable connector groove 622 of the rear coupling surface may grip the exterior of the second cable connector 222. Specifically, the fourth cable connector groove 622 may have a fourth cable connector groove width ccoW4, a fourth cable connector groove depth ccoD4, and a fourth cable connector groove height ccoH4. Referring to FIGS. 4A, 4B, and 9B, the fourth cable connector groove width ccoW4 may be equal to the second width W2. The fourth cable connector groove height ccoH4 may be equal to the second height H2. The fourth cable connector groove depth ccoD4 may be less than the second depth D2. However, embodiments are not limited thereto, and the fourth cable connector groove depth ccoD4 may be equal to or greater than the second depth D2. Also, the fourth cable connector groove width ccoW4, the fourth cable connector groove depth ccoD4, and the fourth cable connector groove height ccoH4 may be set such that the fourth cable connector groove 622 grips the exterior of the second cable connector 222.

When the second cable connector 222 is gripped in the fourth cable connector groove 622, the movement restriction wall 623 may prevent the second cable connector 222 from moving in the (−)Y-axis direction.

When the second cable connector 222 is gripped on the rear coupling surface, a portion of a second cable 212 may be seated on the cable groove and the second cable 212 may extend in the (−)Y-axis direction. Therefore, the cable groove width coW may be greater than the width of the second cable 212. The cable groove height coH may be greater than the thickness of the second cable 212.

Referring to FIGS. 4A, 4B, 9A, and 9B, the fourth cable connector groove depth ccoD4 may be greater than the third cable connector groove depth ccoD3 by the depth difference dD. Also, the third cable connector groove height ccoH3 may be greater than the fourth cable connector groove height ccoH4 by the height difference dH. In addition, the third cable connector groove width ccoW3 may be greater than the fourth cable connector groove width ccoW4 by the width difference dW. Accordingly, the front coupling surface of the multi connector grip 600 may have a structure that matches the first cable connector 221. The rear and front coupling surfaces of the multi connector grip 600 may overlap each other in the Y-axis direction.

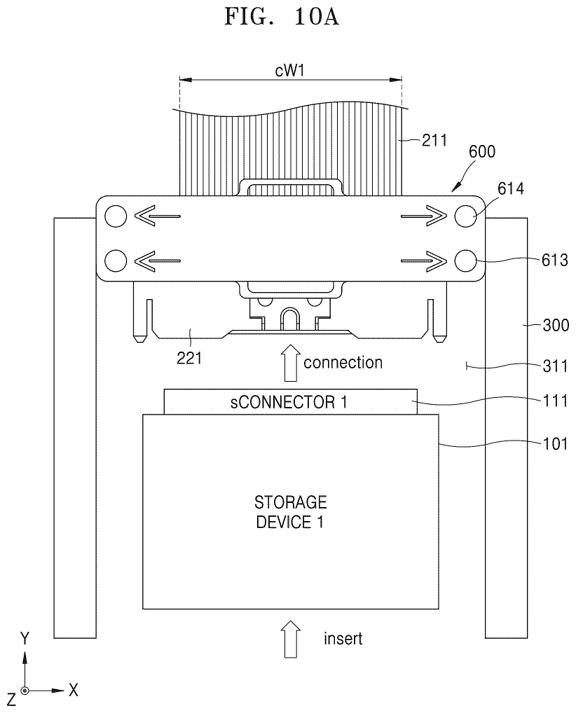

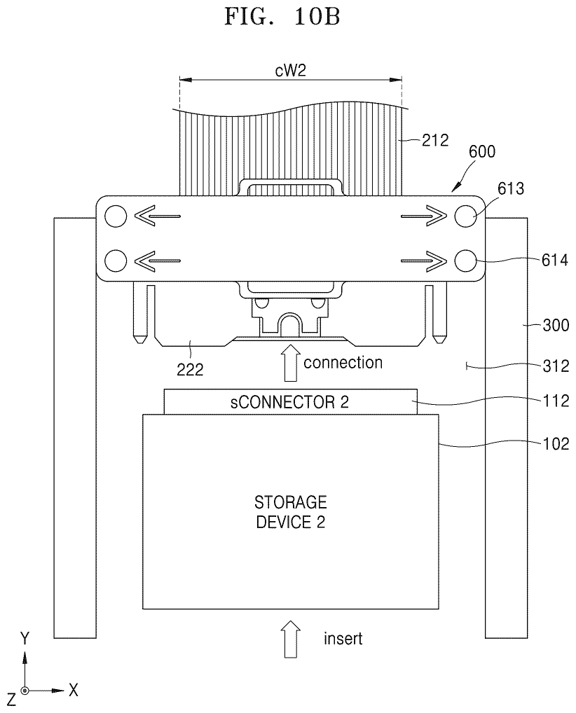

FIGS. 10A and 10B are views illustrating the multi connector grip 600 according to one or more embodiments.

Referring to FIG. 10A, the multi connector grip 600 may be coupled to the storage rack 300 such that the front coupling surface of the multi connector grip 600 is oriented in the (−)Y-axis direction. Specifically, the multi connector grip 600 may be coupled to a portion of the storage rack 300 (e.g., the board 320 in FIG. 3) by a connection member (e.g., a screw) inserted into the first fixing hole 613. Also, the first cable connector 221 may be fixed inside the multi connector grip 600 by a connection member inserted into the second fixing hole 614.

The first cable 211 may pass through the cable groove between the movement restriction walls 623 of the multi connector grip 600 and extend toward the rear coupling surface of the multi connector grip 600.

In a state in which the first cable connector 221 is gripped, a robot arm 500 may insert a first storage device 101 into a first slot 311. A first storage connector 111 of the first storage device 101 may be connected to the first cable connector 221.

Referring to FIG. 10B, the multi connector grip 600 may be coupled to the storage rack 300 such that the rear coupling surface of the multi connector grip 600 is oriented in the (−)Y-axis direction. Specifically, the multi connector grip 600 may be coupled to a portion of the storage rack 300 (e.g., the board 320 in FIG. 3) by a connection member (e.g., a screw) inserted into the first fixing hole 613. Also, the second cable connector 222 may be fixed inside the multi connector grip 600 by a connection member inserted into the second fixing hole 614.

The second cable 212 may pass through the cable groove between the movement restriction walls 623 of the multi connector grip 600 and extend toward the front coupling surface of the multi connector grip 600.

In a state in which the second cable connector 222 is gripped, the robot arm 500 may insert a second storage device 102 into a second slot 312. The second storage connector 112 of the second storage device 102 may be connected to the second cable connector 222.

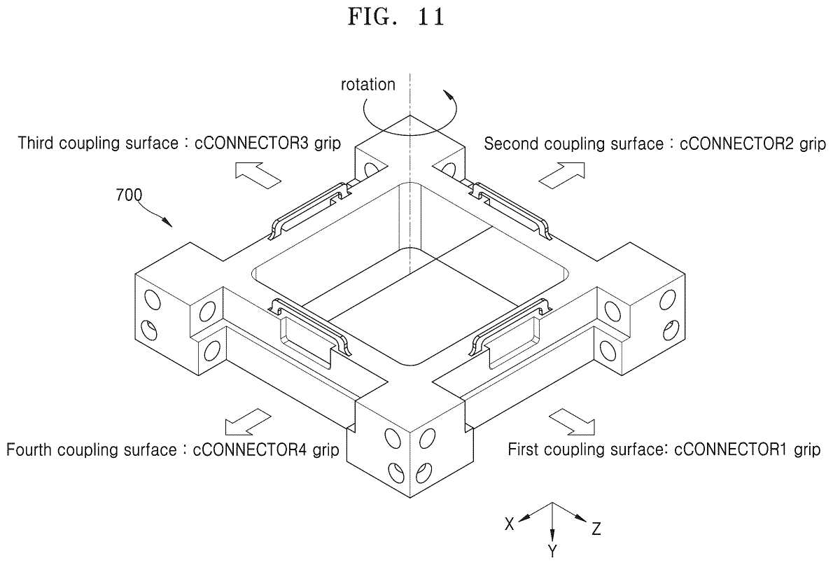

FIG. 11 is a view illustrating a multi connector grip 700 according to one or more embodiments. The multi connector grip 700 may be an example of the multi connector grip 400 of FIG. 1. FIG. 11 may be described with reference to FIG. 1.

Referring to FIG. 11, the multi connector grip 700 may have four coupling surfaces. A first coupling surface may be matched to a first cable connector to grip the first cable connector, a second coupling surface may be matched to a second cable connector, a third coupling surface may be matched to a third cable connector, and a fourth coupling surface may be matched to a fourth cable connector.

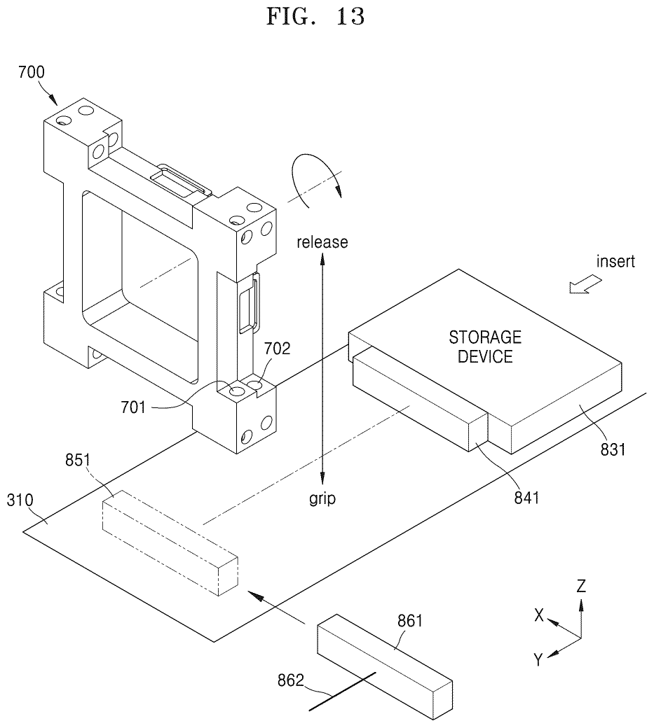

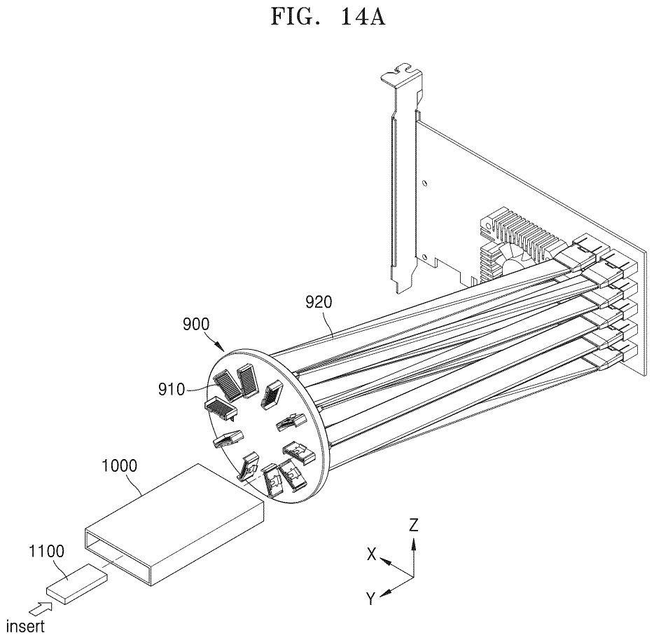

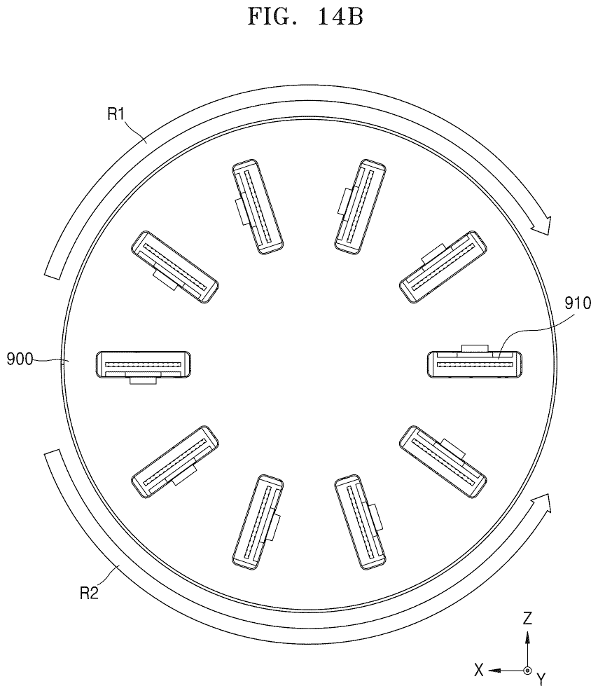

The multi connector grip 700 may rotate clockwise about a rotation axis (Y axis). However, embodiments are not limited thereto. The rotation angles may be determined depending on the types of cable connectors that are optimized to evaluate target signals. A method of determining the rotation angles is described below in detail with reference to FIGS. 13 and 14.

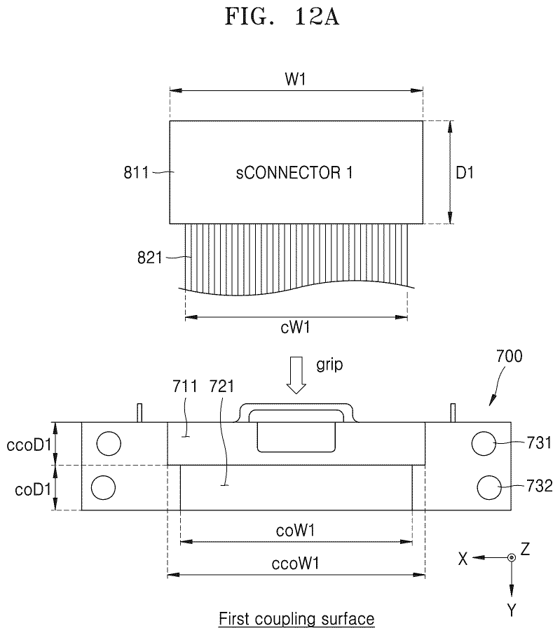

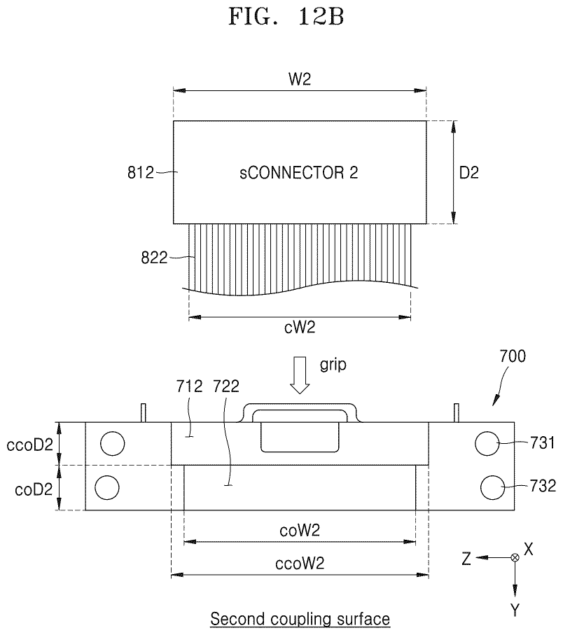

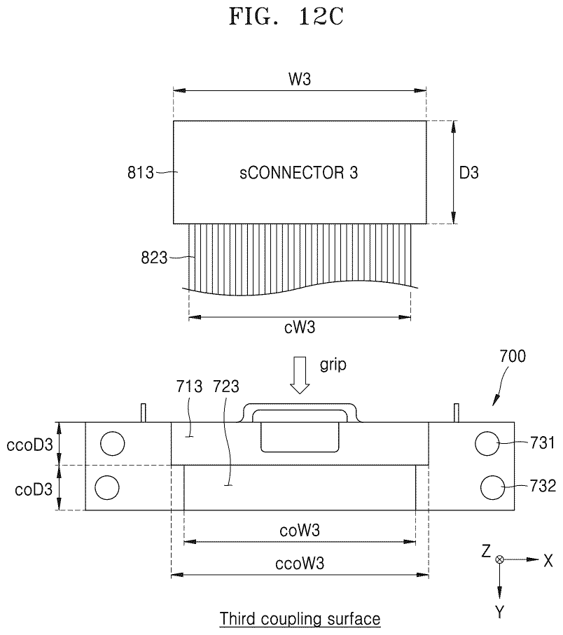

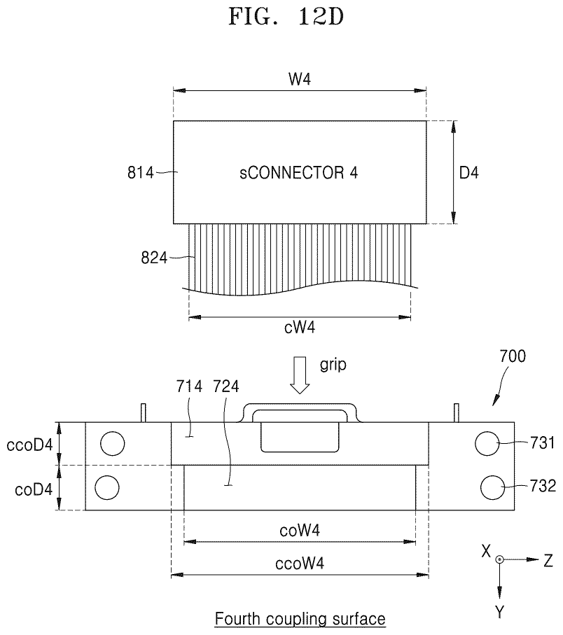

FIGS. 12A to 12D are views respectively illustrating the first to fourth coupling surfaces of the multi connector grip 700 according to one or more embodiments.

Referring to FIG. 12A, a first cable connector groove 711 and a first cable groove 721 may be formed in the first coupling surface of the multi connector grip 700.

The first cable connector groove 711 may have a first cable connector groove width ccoW1 and a first cable connector groove depth ccoD1.

The first cable groove 721 may have a first cable groove width coW1 and a first cable groove depth coD1.

The first coupling surface of the multi connector grip 700 may grip a first cable connector 811 and accommodate a first cable 821. Specifically, the first cable connector 811 may be gripped inside the first cable connector groove 711, and the first cable 821 may be seated on the first cable groove 721.

The first cable connector groove width ccoW1 may be greater than the first cable groove width coW1. Accordingly, the first cable connector 811 gripped in the first cable connector groove 711 may be prevented from being separated in the Y-axis direction.

The outline of the first cable connector 811 may have a rectangular shape with a first width W1 and a first depth D1. However, embodiments are not limited thereto.

The first cable connector groove width ccoW1 of the first cable connector groove 711 may be equal to the first width W1.

The multi connector grip 700 may include a connector fixing hole 731 and a cable fixing hole 732. A connection member (e.g., a screw) passing through the connector fixing hole 731 is coupled to a board (e.g., 320 in FIG. 3), and thus, the first cable connector 811 may be prevented from being separated in the Z-axis direction. A connection member passing through the cable fixing hole 732 is coupled to a board, and thus, the first cable 821 may be prevented from being separated in the X-axis direction.

Referring to FIG. 12B, a second cable connector groove 712 and a second cable groove 722 may be formed in the second coupling surface of the multi connector grip 700. Compared to FIG. 12A, the multi connector grip 700 may be rotated 90 degrees clockwise about the Y axis.

The second cable connector groove 712 may have a second cable connector groove width ccoW2 and a second cable connector groove depth ccoD2.

The second cable groove 722 may have a second cable groove width coW2 and a second cable groove depth coD2.

The second coupling surface of the multi connector grip 700 may grip a second cable connector 812 and accommodate a second cable 822. Specifically, the second cable connector 812 may be gripped inside the second cable connector groove 712, and the second cable 822 may be seated on the second cable groove 722.

The second cable connector groove width ccoW2 may be greater than the second cable groove width coW2. Accordingly, the second cable connector 812 gripped in the second cable connector groove 712 may be prevented from being separated in the Y-axis direction.

The outline of the second cable connector 812 may have a rectangular shape with a second width W2 and a second depth D2. However, embodiments are not limited thereto.

The second cable connector groove width ccoW2 of the second cable connector groove 712 may be equal to the second width W2.

The second depth D2 may be greater than the first depth D1 by a first depth difference dD1. The second cable connector groove depth ccoD2 may be greater than the first cable connector groove depth ccoD1 by a first depth difference dD1. Accordingly, the second cable connector 812 may be inserted deeper into the multi connector grip 700 in the Y-axis direction than the first cable connector 811 by the first depth difference dD1. Therefore, when the robot arm 500 inserts the storage connector (e.g., 111 in FIG. 6B) into the first slot 311, the storage connector and the cable connector may be connected to each other at a constant location regardless of the type of cable connector.

The second width W2 may be greater than the first width W1 by a first width difference dW1. The second cable connector groove width ccoW2 may be greater than the first cable connector groove width ccoW1 by the first width difference dW1. Accordingly, the second coupling surface of the multi connector grip 700 may be matched to the second cable connector 812, and the second cable connector 812 may be gripped more firmly in the second cable connector groove 712 than in the first cable connector groove 711.

Referring to FIG. 12C, a third cable connector groove 713 and a third cable groove 723 may be formed in the third coupling surface of the multi connector grip 700. Compared to FIG. 12B, the multi connector grip 700 may be rotated 90 degrees clockwise about the Y axis. The third coupling surface of the multi connector grip 700 may grip the third cable connector 813 and accommodate the third cable 823, and the third cable 823 may have a third width cW3.

The third cable connector groove 713 may have a third cable connector groove width ccoW3 and a third cable connector groove depth ccoD3. The description of the first or second cable connector groove 711 or 712 may be applied to the third cable connector groove 713.

The third cable groove 723 may have a third cable groove width coW3 and a third cable groove depth coD3. The description of the first or second cable groove 721 or 722 may be applied to the third cable groove 723.

A third depth D3 may be greater than the second depth D2 by a second depth difference dD2. The third cable connector groove depth ccoD3 may be greater than the second cable connector groove depth ccoD2 by a second depth difference dD2. Accordingly, a third cable connector 813 may be inserted deeper into the multi connector grip 700 in the Y-axis direction than the second cable connector 812 by the second depth difference dD2. Therefore, when the robot arm 500 inserts the storage connector (e.g., 111 in FIG. 6B) into the first slot 311, the storage connector and the cable connector may be connected to each other at a constant location regardless of the type of cable connector.

A third width W3 may be greater than the second width W2 by a second width difference dW2. The third cable connector groove width ccoW3 may be greater than the second cable connector groove width ccoW2 by the second width difference dW2. Accordingly, the third coupling surface of the multi connector grip 700 may be matched to the third cable connector 813, and the third cable connector 813 may be gripped more firmly in the third cable connector groove 713 than in the second cable connector groove 712.

Referring to FIG. 12D, a fourth cable connector groove 714 and a fourth cable groove 724 may be formed in the fourth coupling surface of the multi connector grip 700. Compared to FIG. 12C, the multi connector grip 700 may be rotated 90 degrees clockwise about the Y axis. The fourth coupling surface of the multi connector grip 700 may grip the fourth cable connector 814 and accommodate the fourth cable 824, and the fourth cable 824 may have a fourth width cW4.

The fourth cable connector groove 714 may have a fourth cable connector groove width ccoW4 and a fourth cable connector groove depth ccoD4. The description of the first, second, or third cable connector groove 711, 712, or 713 may be applied to the fourth cable connector groove 714.

The fourth cable groove 724 may have a fourth cable groove width coW4 and a fourth cable groove depth coD4. The description of the first, second, or third cable groove 721, 722, or 723 may be applied to the fourth cable groove 724.

A fourth depth D4 may be greater than the third depth D3 by a third depth difference dD3. The fourth cable connector groove depth ccoD4 may be greater than the third cable connector groove depth ccoD3 by a third depth difference dD3. Accordingly, a fourth cable connector 814 may be inserted deeper into the multi connector grip 700 in the Y-axis direction than the third cable connector 813 by the third depth difference dD3. Therefore, when the robot arm 500 inserts the storage connector (e.g., 111 in FIG. 6B) into the first slot 311, the storage connector and the cable connector may be connected to each other at a constant location regardless of the type of cable connector.

A fourth width W4 may be greater than the third width W3 by a third width difference dW3. The fourth cable connector groove width ccoW4 may be greater than the third cable connector groove width ccoW3 by the third width difference dW3. Accordingly, the fourth coupling surface of the multi connector grip 700 may be matched to the fourth cable connector 814, and the fourth cable connector 814 may be gripped more firmly in the fourth cable connector groove 714 than in the third cable connector groove 713.

FIG. 13 is a view illustrating operation of the multi connector grip 700 according to one or more embodiments. FIG. 13 may be described with reference to FIG. 1. Descriptions given with reference to the above drawings are omitted.

Referring to FIG. 13, a storage device 831 may be inserted into a slot 310. For example, the robot arm 500 may identify the slot 310 based on the coordinates of the slot 310 and insert the storage device 831 into the slot 310.

In order to connect a storage connector 841 of the storage device 831 and a second cable connector 861 to each other, a multi connector grip 700 may rise in the Z-axis direction. When the multi connector grip 700 rises in the Z-axis direction, a gripping state formed by the multi connector grip 700 is changed into a releasing state and a first cable connector 851 may move.

When the first cable connector 851 is removed, the second cable connector 861 may move to the slot 310. The multi connector grip 700 may be rotated such that a coupling surface corresponding to the second cable connector 861 among the four coupling surfaces of the multi connector grip 700 is oriented in the (−)Z-axis direction. The multi connector grip 700 may descend in the Z-axis direction and grip the second cable connector 861. The multi connector grip 700 and the slot 310 may be coupled and fixed to each other via a cable fixing hole 701 and a connector fixing hole 702.

The storage device 831 may move toward the second cable connector 861, and the storage connector 841 and the second cable connector 861 may be connected to each other.

A second cable 862 connected to the second cable connector 861 may be connected to a test device (e.g., 200 in FIG. 1), and the test device 200 may test the storage device 831.

FIGS. 14A and 14B are views illustrating a rotatable multi connector grip 900 according to one or more embodiments. FIGS. 14A and 14B may be described with reference to FIG. 1.

Referring to FIG. 14A, a storage device 1100 may be inserted into a slot 1000. For example, a robot arm 500 may insert the storage device 1100 into the slot 1000.

The rotatable multi connector grip 900 may include a plurality of cable connectors 910 and a plurality of cables 920 connected to the plurality of cable connectors 910.

The plurality of cable connectors 910 may be fixed to a rotating disc. When the storage device 1100 is inserted into the slot 1000, the rotatable multi connector grip 900 may be rotated so that a required cable connector is connected to a storage connector of the storage device 1100. Unlike the multi connector grips 400, 600, and 700 described above with reference to FIGS. 1 to 13, no time is required to fix the cable connectors 910 to the slot 1000, and thus, test operations may be performed quickly.

Referring to FIG. 14B, the rotatable multi connector grip 900 may rotate in a first rotation direction R1 or a second rotation direction R2. The rotatable multi connector grip 900 may include the plurality of cable connectors 910. For example, first to tenth ports may be provided and the first to tenth ports may support different form factors. That is, the first to tenth ports may have the same pin map, but the exterior specifications of cable connectors may be different from each other.

A cable connector 910, located at a specific position, among the cable connectors 910 included in the rotatable multi connector grip 900 may be connected to the storage connector of the storage device 1100. For example, the cable connector located at 3 o'clock may be connected to the storage connector. Therefore, when the storage device 1100 is inserted, the rotatable multi connector grip 900 may rotate in the first rotation direction R1 or the second rotation direction R2 so that the storage connector and the cable connector optimized for the signal to be evaluated are connected to each other.

The first to tenth ports are connected to respective cables, and thus, entanglement between the cables may occur when the rotation angle increases. When the first to fifth ports are selected as optimized cable connectors, the rotatable multi connector grip 900 may rotate in the second rotation direction R2. Also, when the sixth to tenth ports are selected as optimized cable connectors, the rotatable multi connector grip 900 may rotate in the first rotation direction R1. Accordingly, the entanglement between the cables may be minimized. In some embodiments, the storage device testing system may include a plurality of multi connector grips, and each of the plurality of multi connector grips may correspond to any one of the multi connector grip 400 described above with reference to FIGS. 1 to 7B, the multi connector grip 600 described above with reference to FIGS. 8 to 10B, the multi connector grip 700 described above with reference to FIGS. 11 to 13, and the multi connector grip 900 described above with reference to FIGS. 14A to 14B. For example, the storage device testing system may include a first multiple connector grip and a second multiple connector grip, the first cable connector and a first storage connector may be connected to each other at a first coupling surface of the first multiple connector grip, and the second cable connector and a second storage connector may be connected to each other at a second coupling surface of the second multiple connector grip, the first coupling surface of the first multi connector grip and the second coupling surface of the second multi connector grip may have different structures, a third coupling surface of the first multi connector grip and the second coupling surface of the second multi connector grip may have the same structure, and a fourth coupling surface of the second multi connector grip and the first coupling surface of the first multi connector grip may have the same structure. Moreover, in one embodiment, differences between depths, heights, or widths of a plurality of cable connector grooves corresponding to a plurality of cable connectors may be equal to differences between the depths, the heights, or the widths of the plurality of cable connectors, respectively.

While certain example embodiments have been particularly shown and described, it will be understood that various changes in form and details may be made therein without departing from the spirit and scope of the following claims.

What is claimed is:

1. A multi connector grip comprising:
a first surface comprising a first cable connector groove configured to accommodate a first cable connector, the first cable connector groove having a first cable connector groove depth and the first cable connector having a first depth; and
a second surface opposite to the first surface and comprising a second cable connector groove configured to accommodate a second cable connector, the second cable connector groove having a second cable connector groove depth and the second cable connector having a second depth,
wherein a difference between the first cable connector groove depth and the second cable connector groove depth is equal to a difference between the first depth and the second depth.

2. The multi connector grip of claim 1, wherein the first cable connector has a first height, and the second cable connector has a second height,
wherein the first cable connector groove has a first cable connector groove height, and the second cable connector groove has a second cable connector groove height, and
wherein a difference between the first cable connector groove height and the second cable connector groove height is equal to a difference between the first height and the second height.

3. The multi connector grip of claim 1, wherein the first cable connector has a first width, and the second cable connector has a second width,
wherein the first cable connector groove has a first cable connector groove width, and the second cable connector groove has a second cable connector groove width, and
wherein a difference between the first cable connector groove width and the second cable connector groove width is equal to a difference between the first width and the second width.

4. The multi connector grip of claim 1, wherein the first surface further comprises a first cable groove configured to accommodate a first cable connected to the first cable connector,
wherein the first cable connector groove has a first cable connector groove width, and the first cable groove has a first cable groove width, and
wherein the first cable connector groove width is greater than the first cable groove width.

5. The multi connector grip of claim 1, wherein the second surface further comprises a second cable groove configured to accommodate a second cable connected to the second cable connector,
wherein the second cable connector groove has a second cable connector groove width, and the second cable groove has a second cable groove width, and
wherein the second cable connector groove width is greater than the second cable groove width.

6. The multi connector grip of claim 1, further comprising a connector fixing hole configured to have a connection member inserted therein,
wherein the connection member is further configured to be connected to a storage rack into which a storage device connected to the first cable connector or the second cable connector is inserted.

7. The multi connector grip of claim 1, further comprising a cable fixing hole configured to have a connection member inserted therein,
wherein the connection member is further configured to fix the first cable connector or the second cable connector to an inside of the multi connector grip.

8. The multi connector grip of claim 1, wherein the first surface and the second surface overlap each other in a vertical direction.

9. The multi connector grip of claim 1, wherein the first surface and the second surface overlap each other in a horizontal direction.

10. The multi connector grip of claim 1, further comprising:
a third surface comprising a third cable connector groove having a third cable connector groove depth and configured to accommodate a third cable connector having a third depth; and
a fourth surface comprising a fourth cable connector groove having a fourth cable connector groove depth and configured to accommodate a fourth cable connector having a fourth depth.

11. A storage device test system comprising:
a storage rack comprising a first slot and a second slot;
a first storage device inserted into the first slot and comprising a first storage connector;
a second storage device inserted into the second slot and comprising a second storage connector;
a test device configured to test the first storage device and the second storage device;
a first cable connector connected to a first cable extending from the test device;
a second cable connector connected to a second cable extending from the test device;
a first multi connector grip coupled to the first slot and configured to fix a position of the first cable connector; and
a second multi connector grip coupled to the second slot and configured to fix a position of the second cable connector,
wherein the first cable connector and the first storage connector are connected to each other at a first coupling surface of the first multi connector grip,
wherein the second cable connector and the second storage connector are connected to each other at a second coupling surface of the second multi connector grip,
wherein the first coupling surface of the first multi connector grip and the second coupling surface of the second multi connector grip have different structures,
wherein a third coupling surface of the first multi connector grip and the second coupling surface of the second multi connector grip have a same structure, and
wherein a fourth coupling surface of the second multi connector grip and the first coupling surface of the first multi connector grip have a same structure.

12. The storage device test system of claim 11, wherein the first cable connector has a first depth, and the second cable connector has a second depth,
wherein the first coupling surface of the first multi connector grip has a first cable connector groove depth, and the second coupling surface of the second multi connector grip has a second cable connector groove depth, and
wherein a difference between the first cable connector groove depth and the second cable connector groove depth is equal to a difference between the first depth and the second depth.

13. The storage device test system of claim 11, wherein the first cable connector has a first height, and the second cable connector has a second height,
wherein the first coupling surface of the first multi connector grip has a first cable connector groove height, and the second coupling surface of the second multi connector grip has a second cable connector groove height, and
wherein a difference between the first cable connector groove height and the second cable connector groove height is equal to a difference between the first height and the second height.

14. The storage device test system of claim 11, wherein a concave dip structure is provided on an upper surface of the second cable connector, and
wherein a convex protruding structure is provided on the second coupling surface of the second multi connector grip at a position contacting the concave dip structure.

15. The storage device test system of claim 11, wherein the first coupling surface of the first multi connector grip comprises:
a first cable connector groove in which the first cable connector is accommodated; and
a first cable groove in which the first cable is accommodated,
wherein the first cable connector groove has a first cable connector groove width,
wherein the first cable groove has a first cable groove width,
wherein the first cable connector groove width is greater than the first cable groove width,
wherein the second coupling surface of the second multi connector grip comprises:
a second cable connector groove in which the second cable connector is accommodated; and
a second cable groove in which the second cable is accommodated,
wherein the second cable connector groove has a second cable connector groove width,
wherein the second cable groove has a second cable groove width, and
wherein the second cable connector groove width is greater than the second cable groove width.

16. The storage device test system of claim 11, wherein the first coupling surface and the third coupling surface of the first multi connector grip overlap each other in a vertical direction, and
wherein the second coupling surface and the fourth coupling surface of the second multi connector grip overlap each other in the vertical direction.

17. The storage device test system of claim 11, wherein the first coupling surface and the third coupling surface of the first multi connector grip overlap each other in a horizontal direction, and
wherein the second coupling surface and the fourth coupling surface of the second multi connector grip overlap each other in the horizontal direction.

18. An automated storage device test system comprising:
a storage rack comprising a first slot and a second slot;
a robot arm configured to, based on coordinates of the first slot and the second slot, insert a first storage device into the first slot and a second storage device into the second slot;
a test device configured to test the first storage device and the second storage device;
a first cable connector connected to a first cable extending from the test device;
a second cable connector connected to a second cable extending from the test device;
a first multi connector grip coupled to the first slot and configured to fix a position of the first cable connector; and
a second multi connector grip coupled to the second slot and configured to fix a position of the second cable connector,
wherein the first cable connector and a first storage connector of the first storage device are connected to each other at a first coupling surface of the first multi connector grip,
wherein the second cable connector and a second storage connector of the second storage device are connected to each other at a second coupling surface of the second multi connector grip, and
wherein the first coupling surface of the first multi connector grip and the second coupling surface of the second multi connector grip have different structures.

19. The automated storage device test system of claim 18, wherein the first cable connector has a first depth, and the second cable connector has a second depth,
wherein the first coupling surface of the first multi connector grip has a first cable connector groove depth, and the second coupling surface of the second multi connector grip has a second cable connector groove depth, and
wherein a difference between the first cable connector groove depth and the second cable connector groove depth is equal to a difference between the first depth and the second depth.

20. The automated storage device test system of claim 18, wherein the first cable connector has a first height, and the second cable connector has a second height,
wherein the first coupling surface of the first multi connector grip has a first cable connector groove height, and the second coupling surface of the second multi connector grip has a second cable connector groove height, and
wherein a difference between the first cable connector groove height and the second cable connector groove height is equal to a difference between the first height and the second height.
